(19) United States
(12) Patent Application Publication
(10) Pub. No.: US 2008/0189941 A1
(43) Pub. Date: Aug. 14, 2008

(54) Method of Manufacture of Electronic or Functional Devices

(75) Inventor: Paul R. Drury, Hertfordshire (GB)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Xaar Technology Limited, Cambridgeeshire (GB)

(21) Appl. No.: 11/631,064

(22) PCT Filed: Jun. 29, 2005
(86) PCT No.: PCT/GB2005/002540

§ 371 Date: Nov. 29, 2007

(30) Foreign Application Priority Data
Jun. 29, 2004 (GB) 0414487.9

(51) Int. Cl. H05K 3/20

(52) U.S. Cl. 29/831; 29/600; 29/601; 343/700 MS

(57) ABSTRACT

Plastic or other electronic devices are formed on a flexible substrate using inkjet printing techniques. To avoid registration difficulties arising from distortion of the substrate, deposition is conducted on a rigid substrate to which a release layer is applied. After application of a type layer which serves as the permanent, flexible substrate, the structure is released from the temporary rigid substrate.

This invention relates to the manufacture of electronic or functional devices.

It is a common requirement for such devices to be formed on a flexible substrate, sometimes in the form of a flexible printed circuit board analogous in function to a “conventional” printed circuit board, but sometimes in forms where the support of electronic devices is an auxiliary function of the substrate. Examples of this form of substrate are plastics credit cards and “paper-like” vouchers, tickets and other documents.

It has already been proposed to use techniques borrowed from the field of inkjet printing to deposit regions of material in the formation of electronic devices. This deposited material may be metallic in nature and serve to form conductor tracks. Dielectric material can be deposited. It has also been proposed to form entire devices from deposited material, taking advantage—for example—of polymeric conductors and semiconductors. In this arrangement, the deposited material can be dielectric, semiconductor, dopant, conductor or an etchant or solvent to form a hole in a previously deposited region of material. In this context, reference is directed to WO 2001/46987 which describes in detail techniques similar to inkjet printing for forming plastics electronic devices on plastics or other substrates.

A difficulty is encountered in the use of inkjet printing techniques to form electronic devices on flexible substrates where the interaction of the deposited liquid with the substrate leads to changes in the orientation of the substrate which in turn lead to alignment difficulties with subsequently deposited regions. In one example, a deposited fluid may cause a substrate to swell. This is however, just an example, and difficulties in alignment with a flexible substrate can arise from a wide variety of thermal, humidity, chemical and mechanical effects.

These difficulties can lead to increased cost and complexity in maintaining alignment and registration of subsequent manufacturing processes, notwithstanding changes in the orientation of the substrate. Alternatively, or additionally, these difficulties may place constraints on the nature of the substrate material that can be employed, the thickness or inherent flexibility of the substrate, and the available deposition processes.

It is an object of the present invention to provide a new method of manufacture of electronic devices on a flexible substrate which avoids or ameliorates some or all of the above difficulties.

Accordingly, the present invention consists in one aspect in electronic or functional apparatus having a plurality of electronic or functional devices on a flexible substrate, comprising the steps of providing a rigid substrate having a deposition surface; forming a release layer on the deposition surface; depositing a plurality of regions of material on the release layer to form an array of devices; releasing the array of devices from the deposition surface; bonding a flexible substrate to the said array, preferably, wherein at least some of said plurality of regions of material are deposited as liquid droplets.

Advantageously, the step of releasing the array of electronic devices from the deposition surface occurs after the step of bonding a flexible substrate to the said array.

In another aspect, the present invention consists in electronic or functional apparatus having a plurality of electronic or functional devices on a plastics substrate, comprising the steps of providing a rigid substrate having a deposition surface; depositing droplets of liquid to form at least in part an array of devices; bonding a plastics substrate to the said array and, subsequent to the bonding of said plastics substrate to the array, releasing the array from the deposition surface.

Suitably, the devices are formed substantially of polymeric material.

Advantageously, the step of bonding a substrate comprises the step of applying a substrate material in fluid form and causing said fluid to solidify to form a substrate.

Preferably, the flexible or plastics substrate is apertured to permit access to said electronic devices.

Aspects of the present invention provide process sequences, particularly but not exclusively for the deposition of materials via inkjet, which minimise substrate stability issues.

In forms of the present invention, a reusable stable substrate is chosen, perhaps of a glass, ceramic or metallic material. A release layer is applied to one side. This might be a release agent or a material that can be later removed by as etching, heating, peeling (mechanical) or other material removal process. Application of the release layer might be by wet plating, spinning, inkjet deposition or other processes. Since the release layer is applied to the entire deposition surface of the substrate, a low cost process can and should be employed. Regions of liquid material to form plastics electronics devices are then deposited onto the top of the release layer. Since the substrate is rigid, multiple such layers can readily be formed without the need for complex measurement and alignment systems. Once completed, the deposited structure can be released from the substrate, for subsequent application to a flexible substrate. Alternatively, and especially in the case where the multiple deposited layers are delicate, a flexible substrate layer can be attached to the side of the structure opposing the rigid substrate, prior to release of the structure from the rigid substrate.

Application of the substrate layer could be by fluid spray, bar coating, spinning or other suitable techniques.

An additional embodiment is one wherein the flexible substrate is attached to the rigid substrate by inkjet deposition, spray or others as a first step, preferably with some form of release layer. Advantageously this flexible substrate is free from defects and contamination that is likely to result following its manufacture due to handling and storage operations. This is likely to produce a higher yielding process. Inkjet materials are then deposited on top of this ‘virgin’ flexible substrate in a plurality of layers to form the electronic or functional devices. Optionally another flexible layer could be added to the structure prior to release.

Conventionally one would think of a substrate for electronic or functional devices as being dielectric and this might well be a preferred embodiment. However, certain devices will require that the outer layer be conductive (perhaps to form a shield layer for EMC purposes or even as a means of providing a heatsink, for example) so that the flexible substrate might be metallic and deposited by electro or electroless plating methods, vacuum methods, inkjet deposition or otherwise.

The invention will now be described in more detail by way of example with reference to the accompanying drawings in which:

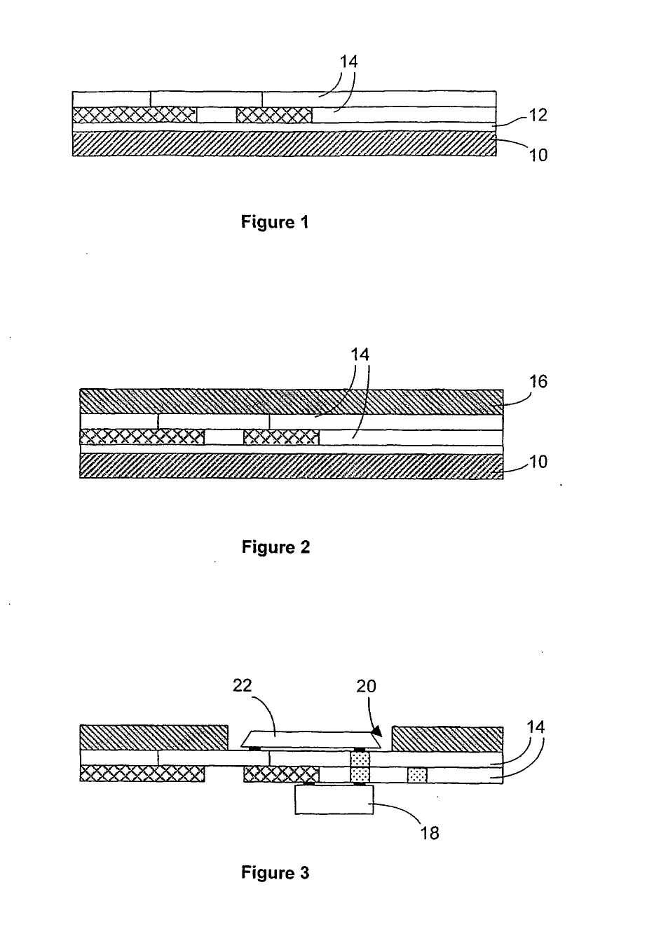

FIGS. 1 and 2 are sectional views illustrating steps in a method according to the present invention.

FIG. 3 is a similar sectional view illustrating a modification.

Referring to the drawings, a substrate 10 is employed of a rigid material. The substrate may be formed of glass, ceramic or metallic material and may be arranged to be reusable. The substrate will be rigid and stable and will in many applications be flat. Arrangements are, however, contemplated in which a cylindrical substrate is employed to enable continuous rather than batch mode manufacturing processes.

A release layer 12 is applied to a deposition surface of the substrate. This release layer may take the form of material deposited by a variety of techniques such a wet plating, spinning or inkjet deposition to form a layer which maintains the stability of the substrate 10 but which can be removed in a subsequent etching, heating or other removal process. The release layer may take the form of a known release agent. The release layer may also take the form of a surface treatment which provides on the substrate a deposition surface which provides temporary adhesion of deposited materials, the temporary adhesion being sufficient to maintain the stability of the substrate, yet permit subsequent release of the deposited structure.

As shown generally at 14, a plurality of regions of material are deposited in multiple layers to form electronic devices. The precise nature of the devices and the manner in which these regions of material are formed are not essential features of the present invention and the skilled man will have available to him a wide variety of arrangements and techniques. Reference is directed, for example, to WO 2001/46987.

Turning now to FIG. 2, once the multiple layer 14 are complete, a permanent carrier substrate 16 is deposited. This may take the form of a solid substrate layer bonded to the upper surface of the multiple layers 14. Preferably, the permanent carrier substrate layer is formed by the deposition of fluid (which may be gaseous, particulate or liquid) which subsequently solidifies or aggregates to form a flexible substrate. The carrier substrate may, for example, be formed by spray, bar-coating, or spinning techniques.

Turning now to FIG. 3, it will be seen that additional components such as that illustrated schematically at 18, can be bonded to the surface of the mult-layer structure 14 that has been released from the temporary substrate. Additionally, apertures such as 20 can be formed in the permanent substrate, to permit components such as that shown schematically at 22 to be connected to the opposing surface of the multi-layer structure 14.

It should be understood that this invention has been described by way of example and a variety of modifications are possible without departing from the scope of the invention as set forth in the accompanying claims. Thus the example has been taken of electronic devices which might include semi conductive or other switching devices; optoelectronic devices such as display element or photo-sensors; and a variety of electronic transducers. The invention is more broadly applicable to the formation of functional devices which are not necessarily electronic and includes magnetic, optical, chemical and mechanical devices capable of being formed by the deposition of a plurality of regions of material, preferably by ink jet printing techniques.

1. Method of manufacturing electronic or functional apparatus having a plurality of electronic or functional devices on a flexible substrate, comprising the steps of providing a rigid substrate having a deposition surface; forming a release layer on the deposition surface; depositing a plurality of regions of material on the release layer to form an array of devices; releasing the array of devices from the deposition surface; and bonding a flexible substrate to the said array.

2. Method according to claim 1, comprising depositing at least some of said plurality of regions of material as liquid droplets.

3. Method according to claim 1, wherein the step of releasing the array of devices from the deposition surface occurs after the step of bonding a flexible substrate to the said array.

4. Method according to claim 1, wherein the step of bonding a flexible substrate occurs immediately after the step of forming a release layer on the deposition surface.

5. Method of manufacturing electronic or functional apparatus having a plurality of electronic or functional devices on a plastics substrate, comprising the steps of providing a rigid substrate having a deposition surface; depositing droplets of liquid to form at least in part an array of devices; bonding a plastic substrate to the said array and, subsequent to the bonding of said plastics substrate to the array, releasing the array from the deposition surface.

6. Method according to claim 1, wherein the devices are formed substantially of polymeric material.

7. Method according to claim 1, wherein the step of bonding a substrate comprises the step of applying a substrate material in fluid form and causing said fluid to solidify to form a substrate.

8. Method according to claim 1, wherein the flexible or plastic substrate is apertured to permit access to said devices.

9. Method according to claim 2, wherein the step of releasing the array of devices from the deposition surface occurs after the step of bonding a flexible substrate to the said array.

10. Method according to claim 2, wherein the step of bonding a flexible substrate occurs immediately after the step of forming a release layer on the deposition surface.

11. Method according to claim 5, wherein the devices are formed substantially of polymeric material.

12. Method according to claim 5, wherein the step of bonding a substrate comprises the step of applying a substrate material in fluid form and causing said fluid to solidify to form a substrate.

13. Method according to claim 5, wherein the flexible or plastic substrate is apertured to permit access to said devices.
